(19) United States
(12) Patent Application Publication
(10) Pub. No.: US 2012/0261703 A1
(43) Pub. Date: Oct. 18, 2012

(54) Self-cooling solid-state emitters

(76) Inventors: Scott M. Zimmerman, Basking Ridge, NJ (US); William R. Livesay, San Diego, CA (US); Richard L. Ross, Del Mar, CA (US); Eduardo DeAnda, San Diego, CA (US); Chad R. Livesay, Encinitas, CA (US)

(21) Appl. No.: 13/506,015

(22) Filed: Mar. 21, 2012

Related U.S. Application Data
(60) Provisional application No. 61/465,611, filed on Mar. 21, 2011.

(51) Int. Cl. H01L 33/64; H01L 33/50

(52) U.S. Cl. 257/98; 257/E33.075; 257/E33.061

(57) ABSTRACT

A self-cooling emitter is a light emitting element embedded within a thermally conductive luminescent element which functions as a thermal cooling means and wavelength conversion of the light emitting element. The thermally conductive luminescent element exhibits a bulk thermal conductivity greater than 1 W/m/K such that there is sufficient thermal spreading of the heat generated by the light emitting element.

### REFERENCE TO PRIOR APPLICATION

This application claims the benefit of U.S. Provisional Patent Application Ser. No. 61/465,611, which was filed on Mar. 21, 2011, which is herein incorporated by reference.

### TECHNICAL FIELD

The present invention is a solid-state light source containing at least one self-cooling emitter. The self-cooling emitter is a light emitting element embedded within a thermally conductive luminescent element which functions as a optical distribution system, thermal cooling means, wavelength conversion of the light emitting elements, and mechanical support/package for connectors, drivers, sensors, and optical diffusing elements. The thermally conductive luminescent element exhibits a bulk thermal conductivity greater than 1 W/m/K such that there is sufficient thermal spreading of the heat generated by the light-emitting element. Additionally, methods of manufacturing and designs for LEDs for use in self-cooling emitters are also disclosed.

### BACKGROUND OF THE INVENTION

The cost of solid-state lighting is typically driven by two main elements, namely the packaging (drivers, optics, thermal, and interconnect) and the LEDs. Both of these cost drivers must be addressed if significant cost reductions are to be realized. Unfortunately, the LED manufacturers are reducing costs by increasing the lumens/die, which results in higher packaging costs. A need exists for a solution that reduces both packaging and LED costs while still meeting the needs of the lighting community.

Historically, all successful lighting technologies (incandescent, fluorescent, halogen, sodium, etc.) have been self-cooling. This is accomplished through the use of high temperature materials and manufacturing processes such as glass to metal joining. Over the years and as the technology matured these processes and materials led to lightweight packaging. Typically an incandescent bulb generates between 30 and 50 lumens/gram. In comparison, the typical LED lamp generates between 1 and 5 lumens/gram due to the massive heatsinks, optics, drivers, and multiple levels of interconnects required to cool, distribute, and drive the localized LED die or packaged die. In the typical LED lamp, separate elements are used for cooling (metal), optics (plastic), and interconnect (ceramic with metal traces). From a life cost standpoint, cost boils down to grams of material used and the number of separate elements used in the design. Therefore the need exists for solid state solutions which reduce the total mass of material used and number of elements used while still maintaining the required performance regarding cooling the LEDs, forming the desired optical output distribution, providing the necessary drive input to the LEDs, and creating a user friendly package that the consumer can handle and install.

In general, solid-state lighting uses hemispherical emitters. Hemispherical emitters are inherently less efficient than isotropic emitters because the photons emitted within the active region of the LED are substantially isotropically emitted. A vast amount of effort and intellectual property has been generated around the most efficient method of reducing the solid angle from spherical to hemispherical or an even narrower emission both internally and externally to the LED. As disclosed in U.S. Pat. No. 7,804,099, these losses can be mitigated by using thermally conductive luminescent elements with embedded LEDs, such that light is extracted out of both sides of the LEDs. Not only does this approach inherently allow for higher efficiency, it also has been demonstrated to generate over 100 lumen/gram output levels by combining the optics, thermal, interconnect and even the drivers within a single element.

Presently, LED manufacturers are reducing LED costs by generating more lumens/die area. The typical LED emits light into one hemisphere while heat is extracted in the other hemisphere. The sources disclosed in this invention emit light and extract heat in the same direction. While LED die have been embedded between glass sheets in the past, these applications have been mainly decorative in nature due to low thermal conductivity of the glass and organic bonding layers used. When the thermal conductivity of the material surrounding the LED die is greater than 1 W/m/K and there is a low thermal resistance between the LED die and the material surrounding the LED die, self cooling light sources can be realized which have sufficient output levels to be useful in general illumination applications where outputs of 100s and 1000s of lumens are required. The need exists for high thermal conductivity packages that allow for high lumen output self-cooling solid-state emitters.

Incandescent and fluorescent lamps typically exhibit surface brightness between 3,000 and 20,000 ftL. Lower surface brightness requires very large source areas and higher brightness levels are unsuitable for direct viewing applications. The use of high thermal conductivity wavelength conversion elements (greater than 1 W/m/K) is disclosed in U.S. Publication Number 20080149166 and U.S. Pat. No. 7,804,009. By combining high thermal conductivity wavelength converting elements with low cost, high temperature, isotropically emitting LEDs embedded within the elements, cost effective, self-cooling solid-state emitters can be realized.

A conventional wavelength conversion material for solid-state lighting typically consists of a phosphor powder that may be embedded in a transparent polymer. The wavelength conversion material can be deposited, for example, as a dome that covers the output surface of the LED. This approach however is similar to embedding LEDs between glass sheets in that the average thermal conductivity is too low to efficiently transfer heat from the LED active region to the surrounding ambient. As an example, CeYag has a bulk thermal conductivity of 14 W/m/K but when it is ground into a powder and dispersed in to the standard silicone matrix used in the majority of LEDs, the thermal conductivity may be as low as 0.1 W/m/K. As such, virtually no heat can be conducted away from the die using this material. Alternately, LEDs mounted between glass sheets are similarly restricted because glass typically has a thermal conductivity of less than 1 W/m/K. In this case, the heat generated cannot be efficiently spread out over a sufficiently large enough surface area such that natural convective cooling can dissipate the heat while maintaining a die junction temperature within acceptable limits. The life of any LED is directly related to the temperature of the junction. Using high thermal conductivity wavelength conversion elements (greater than 1 W/m/K), it is possible to generate self cooling solid state emitters, relying only on natural convection cooling, emitting over 200 lumens/square inch of source area with a CCT of 3100K CRI over 80 while maintaining a LED junction temperatures under 90 degrees C. The source has surface brightness of approximately 15,000 ftL, is hermetically sealed, and weighs 2 grams.

The standard approach to produce wavelength conversion materials begins by making bulk solid phosphors using solid-state processing, as known in the art. These phosphors are then ground down to powders in the micron size range and deposited on a surface using a variety of deposition techniques such as settling, encapsulation within a polymer matrix, or spray coating. Though relatively inexpensive, the phosphors generated using these methods suffer from high levels of dislocations and lattice defects. In addition, the compositional purity is also difficult to maintain. In the majority of cases, this does not represent a major problem because of the reduced excitation levels. It has been shown in accelerated aging studies, however, that very high excitation levels can degrade the output luminescence of powdered phosphors severely and impact overall life performance. These levels of high excitation exist within solid-state lighting applications. This is mainly due to the small size and concentrated flux density of the LED die itself.

Several material characteristics such as lattice defects, out-gassing, and compositional purity contribute to the problems of light output degradation and/or loss in efficiency for phosphor materials. It has been shown that polycrystalline and mono-crystalline phosphor films, either grown on a substrate or as single crystal boules, tend to exhibit much better luminosity and life characteristics than powders. In addition, every phosphor has a thermal quenching level that can degrade the output at the temperatures created by elevated excitation levels. As an example, CeYag conversion efficiency drops by 10% to 15% at 150 degrees C. In the case of powdered phosphors, this can be a major issue because the phosphor particles are usually isolated from any reasonable thermal conduction path. At very high excitation levels, the energy associated with less than unity quantum efficiency and Stokes shift losses can induce a significant localized thermal rise within the phosphor particles. The need exists for the creation of an improved thermal conduction path for the luminescent material. Also, the scattering created by the use of a powder can reduce the overall light output due to the backscattering and subsequent absorption of the generated light.

Mueller-Mach et al. in U.S. Pat. No. 6,696,703 discloses the deposition of a thin film phosphor directly on the LED die. However, as-deposited thin film phosphors have relatively poor wavelength conversion efficiency. A high-temperature annealing step is required in order to properly activate the phosphor. This annealing step can damage the semiconductor layers of the LED. In addition, the absorption cross-sections of most thin film phosphors are low, especially for blue and near ultraviolet (UV) excitations typically used for solid-state lighting. It is neither economical nor practical in most cases to create a sufficiently thick layer of luminescent material grown directly on the LED. Another drawback to depositing a phosphor directly on the LED die is that a large portion of the light generated within a deposited phosphor layer can be trapped due to total internal reflectance. The need, therefore, exists for a method to utilize high performance phosphors within an LED package such that the best phosphor can be used efficiently (e.g. with sufficient quantity, minimal backscatter, and maximum light extraction). The need also exists for a method to fabricate high efficiency phosphors without damaging the LED semiconductor layers.

Mueller-Mach et al. in U.S. Pat. No. 6,630,691 disclose a thin single-crystal phosphor substrate onto which an LED structure is fabricated by epitaxial growth techniques. However, finding a single crystal phosphor substrate that has the proper lattice match to allow the growth of the LED structure can be difficult and expensive.

U.S. Pat. Nos. 7,285,791, 7,795,600, and 7,804,099 disclose a wavelength conversion chip which allows for not only wavelength conversion, but thermal, optical spreading, and electrical interconnect of embedded LEDs. Additionally, U.S. Patent Publication Numbers 20090173954, 20090221106, 20100060143, 20100247893, and 20100308361 disclose thermally conductive luminescent elements, including composites and layered elements. The intent of this invention is to disclose additional materials, methods and articles for further reducing costs using thermally conductive luminescent elements which combine wavelength conversion, optical spreading, thermal spreading/cooling, and mechanical packaging (e.g. interconnect, connectors, and sensors).

It is be desirable to replace the conventional wavelength conversion material, which is typically a low thermal conductivity organic composite (e.g. silicone matrix with phosphor powder—less than 1 W/m/K), with a solid thermally conductive (e.g. greater than 1 W/m/K), optically spreading and structural wavelength conversion chip to which LEDs can be mounted. By integrating the interconnect into the wavelength conversion chip, arrays of smaller LED die can be connected and high lumen output self-cooling source can be created. In this approach, additional cooling means, optical diffusing means, and interconnect means can be eliminated thereby reducing packaging costs.

A conventional LED package containing an LED and a wavelength-converting phosphor is bulky compared to the light emitting epitaxial-layered structure itself. If many LED packages are used in the solid-state light source, the light source is significantly heavier, and larger than necessary. Existing incandescent lamps output between 30 and 50 lumens/gram. Due to the need for heavy and expensive thermal solutions, existing solid-state lamps output 1 to 5 lumens/gram. Solid-state lamps outputting 500 lumens based on existing approaches can weigh almost 1 lb. For overhead residential applications, this can create a safety issue and require additional hardware to prevent lamps from falling.

U.S. Pat. No. 7,361,938 discloses a ceramic phosphor layer bonded to a conventional LED. In one example, the LED is a flip chip device with both electrodes on the side of the LED opposite the ceramic phosphor so that no electrodes are in the way when bonding the ceramic phosphor layer to the LED. The LED includes a growth substrate that is still attached to the top surface of the semiconductor layers of the LED. The phosphor layer is also bonded to the growth substrate, but on the side opposite the semiconductor layers. In a second example, the p-contact layer of the LED is attached to a transfer (host) substrate and the ceramic phosphor layer is attached to the n-layer opposite the transfer (host) layer. The n-contact is adjacent to the ceramic phosphor layer and on the same side of the LED as the phosphor layer. The original growth substrate has been removed but the transfer substrate remains with the device. In this case, the ceramic phosphor actually increases the thermal load on the LED itself because the heat generated in the phosphor due to Stokes losses and conversion losses must be dissipated through the LED to the heatsink.

U.S. Pat. No. 7,361,938 does not disclose LEDs that have neither a growth substrate nor a transfer substrate as an element of the LED die. U.S. Pat. No. 7,361,938 does not disclose LEDs where the n-type layer, the p-type layer or both the n-type layer and the p-type layers are thick enough so that the multilayer semiconductor structure of the LED is rugged and may be handled as a free-standing chip without having the growth or transfer substrate still attached. In addition, U.S. Pat. No. 7,361,938 does not disclose wavelength conversion chips that include an electrical interconnection means. U.S. Pat. No. 7,361,938 also does not disclose a stack of light emitting chips where one chip is an LED chip and another chip is a wavelength conversion chip that includes an electrical interconnection means. U.S. Pat. No. 7,361,938 does not disclose a stack of light emitting chips where at least two of the chips are LED chips and where the stack optionally includes at least one wavelength conversion chip.

High output conventional solid-state light sources generate the required lumens or power from one large LED die or from an array of closely spaced LED die. Although useful for light sources requiring a small emitting area or etendue, this type of light source has two deficiencies for general lighting applications such as room lighting. One deficiency is that the high output intensity from such a concentrated source can exceeds eye safety standards and can be a safety hazard. It would be desirable instead to make distributed light sources using many smaller light source chips so that light intensity safety standards are not exceeded. To accomplish this, the light source chips need to be inexpensive and easy to handle. Inherently, an array of small LED die spaced out over a reasonable area are more efficient than highly localized large die or closely packed arrays due to thermal and light extraction issues. Alternatively, OLEDs and backlight based light sources suffer from low surface brightness, which requires very large surface areas to generate the desired lumens. Backlight or waveguide based approaches not only incur an additional loss within the waveguide but also still require heatsinking of the LED packages. A need exists for robust self-cooled emitters with high surface brightness such that reasonable sized lighting fixtures can be constructed. In particular, self-cooling emitters would decouple the thermal elements (e.g. heatsinks) from the optical elements (e.g reflectors, diffusers, and decorative elements) which greatly simplifies the fixture design. Existing LED packages require that the fixture designer integrate thermal solutions into their fixture. This invention eliminates that requirement is a key novel element of all the embodiments of this invention.

The deficiencies of conventional solid-state light sources described above can be eliminated by the various embodiments of this invention that are described below in the summary, the figures, and the detailed descriptions of the preferred embodiments.

### SUMMARY OF THE INVENTION

One embodiment of this invention are solid-state light sources that generate more than 30 lumens/gram. Thermally conductive wavelength conversion elements replace the optics, interconnect, and thermal elements typically used in conventional LED lamps. Additionally, drivers, sensors and AC interconnect means may also be incorporated into or mounted to the thermally conductive wavelength conversion elements. If sufficient thermal conductivity is provided by the thermally conductive wavelength conversion element, the heat generated by the LEDs and optionally driver/sensor circuits can be spread out over a sufficient area such that natural convection cooling can be used to cool the device. While induced draft methods, including but not limited to fans, liquid cooling, heatpipes, and electrostatic air movers, can be used to enhance the amount of heat which an emitter surface can dissipate and the use of fixtures and mounting which enhance natural convection are embodiments of this invention, more specifically natural convection can dissipate between 0.5 and 2 W of heat per square inch of surface area while maintaining the surface temperature under 100° C. The surface temperature is an important attribute of any light source for handling and safety issues. In addition, brightness levels must be maintained below a threshold level for eye safety reasons. This is especially true for photobiological reasons within the blue portion of the spectrum. Dual sided emitters provide the maximum surface area for cooling and the maximum emitting surface area for reduced source brightness. These methods and materials can be used to make directional emitters, along with the use of cooling means which extract heat directly out of the thermally conductive wavelength conversion elements via thermal conduction. Alternately, in order to operate at sufficiently high lumen/area output levels to be useful and reduce material costs, the thermal conductivity of the wavelength conversion element needs to be greater than 1 W/m/K with greater than 10 W/m/K preferred and greater than 25 W/m/K even more preferred.

Composites of phosphor powders with organic binders and most glasses suffer from low thermal conductivity. Bulk, layered, and combinations of bulk and layered wavelength conversion elements with greater than 1 W/m/K are disclosed. Various methods for mounting the LED to and within the thermally conductive wavelength conversion materials can be used as a means of controlling the color temperature of the self-cooling source.

Also disclosed are non-luminescent thermally conductive materials with thermally conductive luminescent coating layers. More preferably, the use of materials and processes related to synthetic jewelry, infrared windows, and transparent ceramics are disclosed. Even more preferred, is the use of Skull and Verneuil grown Cubic Zirconia, CVD ZnS, CVD ZnSe, sapphire, sialon, Silicon oxynitride, and Floating Zone YAG crystalline material. Ceramic/glass, ceramic/silicon oxynitride, ceramic/sialon, and other composite materials are also disclosed with thermal conductivity greater than 1 W/m/K.

### BRIEF DESCRIPTION OF THE DRAWINGS

A more detailed understanding of the present invention, as well as other objects and advantages thereof not enumerated herein, will become apparent upon consideration of the following detailed description and accompanying drawings, wherein:

FIG. 1A depicts a prior art conventional LED package mounted on a heatsink. FIG. 1B depicts prior art embedded LEDs between sheets of glass.

FIG. 2A depicts the prior art thermal conduction schematic of a conventional LED Lamp. FIG. 2B depicts the thermal conduction schematic of a self-cooling emitter.

FIG. 3 is a side cross-sectional view of a self-cooling emitter in which wavelength conversion occurs in the bulk and bonding layers.

FIG. 4 illustrates the various optical paths of emitted rays from embedded LEDs and how they can be used to change the overall color temperature of the source.

FIG. 5A depicts an LED die directly bonded to the thermally conductive wavelength conversion material. FIG. 5B depicts a LED die bonded using an intermediate material to the thermally conductive wavelength conversion material. FIG. 5C depicts a LED die embedded within the thermally conductive wavelength conversion material.

FIG. 6 illustrates how the previous LED mountings can change the color temperature of the self-cooling solid-state emitter.

FIG. 7A depicts the output distribution of LEDs embedded in thermally conductive wavelength conversion elements with high doping levels and minimal amount of waveguiding.

FIG. 7B depicts the output distribution of LEDs embedded in thermally conductive wavelength conversion elements with low doping levels and higher levels of waveguiding.

FIG. 8A depicts an embedded LED within a thermally conductive wavelength conversion element with bulk conversion. FIG. 8B depicts an embedded LED within a thermally conductive wavelength conversion element with the wavelength conversion substantially localized. FIG. 8C depicts a both bulk and localized wavelength conversion within the thermally conductive wavelength converter.

FIG. 9A depicts a self-cooling emitter with embedded lateral LEDs in which the wavelength conversion layer is localized in a high temperature bonding layer. FIG. 9B depicts a self-cooling emitter with embedded vertical LEDs in which the wavelength conversion layer is localized in an outer coating layer.

FIG. 10 illustrates the relationship between thermal conductivity of the wavelength conversion layer and the LED junction temperature and overall source life.

FIG. 11A, FIG. 11B, and FIG. 11C depict various shapes possible for the self-cooling emitters.

FIG. 12A is a side cross-sectional view of another substrate-free vertical LED chip with top and bottom printed contacts. FIG. 12B is a single dual sided hermetically sealed emitter package with offset contacts.

FIG. 13 depicts a three element self-cooled emitter.

FIG. 14 depicts a self-cooled emitter with a shrouded connector.

FIG. 15 depicts a self-cooled emitter with a shrouded connector with integrated temperature and motion sensors.

FIG. 16 depicts rapid cooling of low thermal mass light sources.

FIG. 17 depicts a self-cooled emitter with surface features to control the direction of light output.

FIG. 18 shows three light slices meeting on a common vertical axis with their outer edges 120° apart.

FIG. 19 shows a self-cooled light slice powered via USB with a USB connector attached.

FIG. 20 shows a hexagonal arrangement with six light sticks.

FIG. 21 shows two of these hexagonal arranged light slices and hexagonal mirrors with one facing upward and one facing downward forming a high output light source emitting into a 360° solid angle.

FIG. 22 depicts self-cooler emitting light slices arranged in a fanned configuration.

FIG. 23 depicts triangular shaped light slices arranged to form a very decorative but highly functional light source with omnidirectional output.

FIG. 24 shows another arrangement utilizing triangular shaped light slices to form a very compact omnidirectional light source without requiring any external heatsink.

FIG. 25 shows the hexagonal arranged light slices as described above contained in a conventional Edison type light bulb.

FIG. 26 shows a three-stick light slice arrangement attached to a common hub.

FIG. 27 shows the light slices arranged to provide an omnidirectional output contained in linked rings for mechanical rigidity.

FIG. 28 shows one more arrangement of light sticks to form an omnidirectional output light source.

FIG. 29 shows LEDs located on the central flat surfaces of the two hemispheres, to convectively self cool the LEDs and enhance the extraction of light from the thermally conductive wavelength conversion element of the LEDs.

### DETAILED DESCRIPTION OF THE DRAWINGS

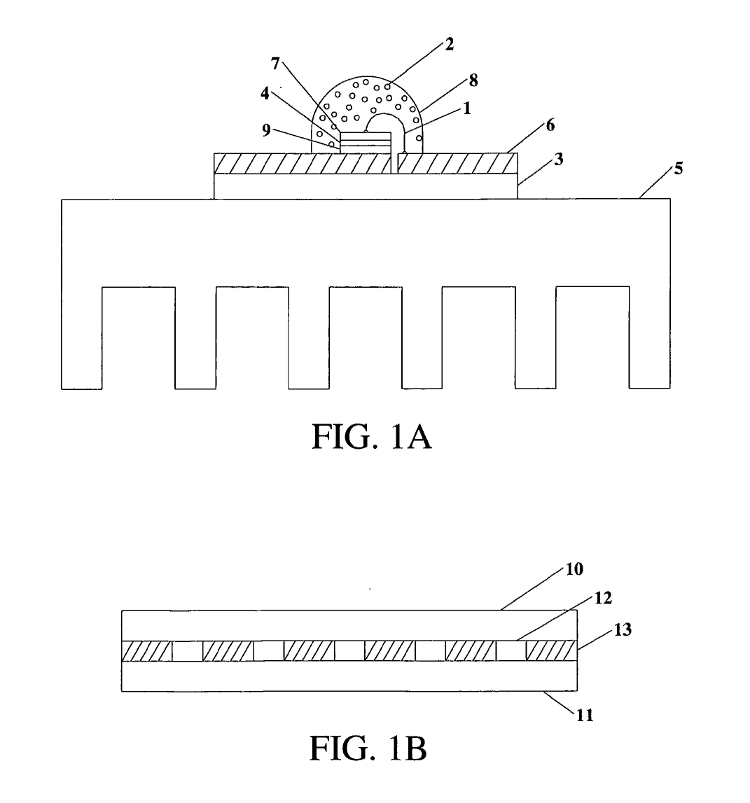

FIG. 1A depicts the typical prior art simplified LED lamp. One or more packaged LEDs or LED die are mounted on a heatsink 5. In the illustration, photons are emitted from LED 7. In most cases a wafer-bonding layer 4 is used to attach the LED 7 to a support mount 9, which is in turn electrically and thermally attached to interconnect 6. Top contact 1 is typically connected to interconnect 6 via wire bonding. Interconnect 6 is typically metal traces formed on a ceramic substrate 3 which allows for external connection to an external power source. Each one of the layers creates additional thermal interfaces, which increases the temperature of the junction for a given input power. In this case, phosphor powders 2 are dispersed within an organic matrix 8 such as silicone or epoxy. The bulk thermal conductivity in this case is less than 1 W/m/K. As such, heat generated both in the LED and within the phosphor powders 2 must be dissipated by conducting heat through the various interconnect layers and eventually through the heatsink 5. In addition, the LED 7 and phosphor powder are protected only by the silicone matrix 9. Moisture, mechanical, and solvents damage can easily occur. More recently, remote phosphor approaches have been used because the flux density and thermal loads have become too high for the phosphor powder 2. However, remote phosphor approaches further increase the volume of the light source, do not provide environmental protection for the die, and can create an eye safety hazard if the remote phosphor optic is removed and the viewer is exposed to the blue LEDs behind the remote phosphor. FIG. 1B depicts LED chips 12 sandwiched between two pieces of ITO coated glass sheets 10 and 11 using an organic adhesive 13. This prior art configuration is typically used for decorative applications due to the low thermal conductivity of the glass sheets 10 and 11 and the localized points of light that are created.

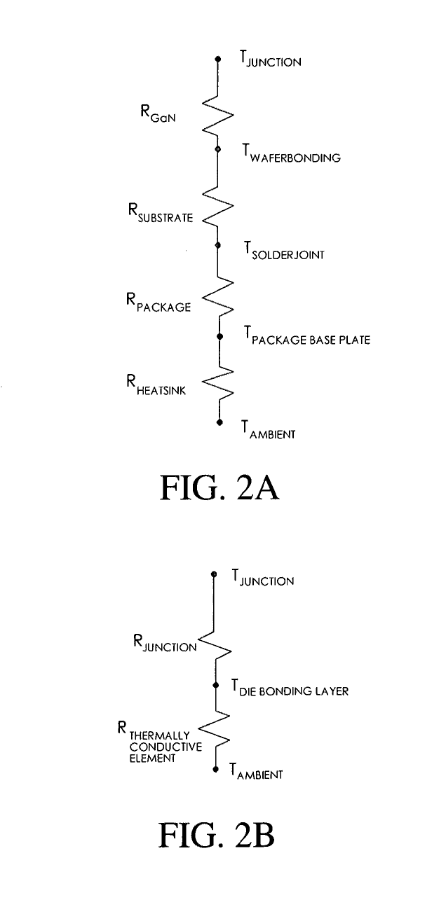

FIG. 2A depicts the thermal schematic of a typical prior art LED lamp. Not only are the thermal resistances of the LED, substrate, package, and heatsink in series between the LED junction and the cooling ambient, but each interface joining layer contributes at least one thermal boundary interface. LED life is directly related to the temperature of the junction of the LED. It is desirable to maintain the operational temperature of the LED junction under 140° C. In addition, the efficiency of the LED lamp is directly related to the temperature and drive level of the LED. As such it is also desirable to maintain low LED temperature and low drive levels.

FIG. 2B depicts the improved thermal schematic of a self-cooling emitter as discussed in this invention. The LED die are embedded within the thermally conductive wavelength converter element, which also acts as a heatsink, optical distribution system, packaging, and interconnect means. In this case, as long as the thermal resistance of the wavelength conversion element is low enough, high lumen outputs can be generated without requiring appended heatsinks. Thermally conductive wavelength conversion elements with thermal conductivity greater than 1 W/m/K are embodiments of this invention. Thermally conductive wavelength conversion elements with thermal conductivity greater than 10 W/m/K are preferred embodiments of this invention. Thermally conductive wavelength conversion elements with thermal conductivity greater than 25 W/m/K are most preferred. T ambient may consist of the surrounding atmosphere, a liquid medium, a heatpipe, a gaseous flow, a forced liquid flow, a thermoelectric means, phase change material or a thermally conductive means for removal of the heat generated within the LED and the thermally conductive wavelength conversion elements. As an example, a total of 1 watt of heat is generated (does not included optical watts emitted from the source) within the system of that 1 watt 50% is typically generated within the LED R(GaN) which is a blue InGaN LED die embedded within a wavelength conversion element and 50% is generated within R(thermally conductive element) which is the wavelength conversion element. The T junction will be determined by the two thermal resistances and amount of heat generated within the LED die and wavelength conversion element. It is recognized that some additional thermal resistance is present within the bonding layer but is not used in this particular example. In general, at least 20% of the heat generated within the various elements of this solid state light source is transferred to T ambient via the thermally conductive wavelength conversion element is a preferred embodiment of this invention. Even more preferably, at least 50% of the heat generated within this solid state light source is transferred to T ambient via the thermally conductive wavelength conversion element is a preferred embodiment of this invention.

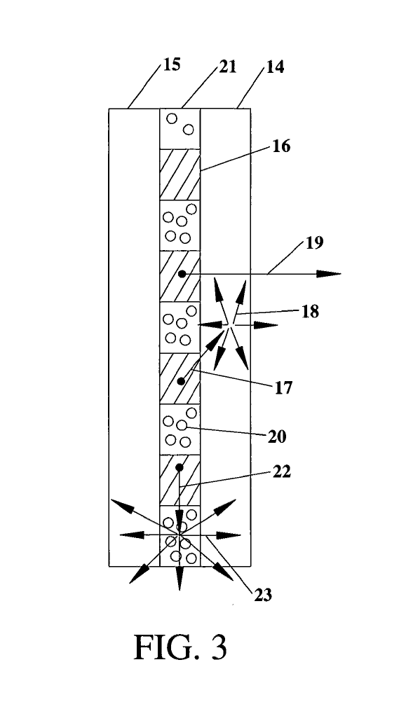

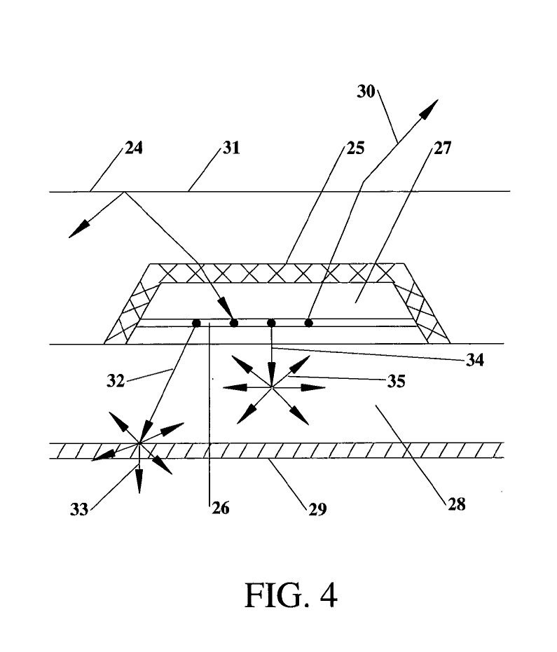

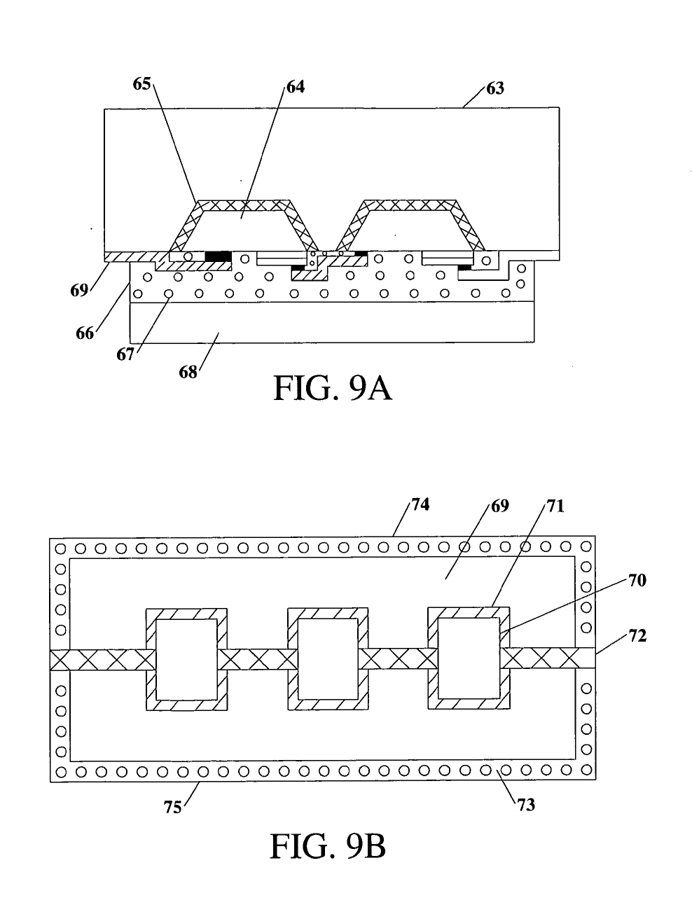

FIG. 3 depicts a cross-section view of a self-cooled emitter. One or more LEDs 16 are sandwiched between wavelength conversion elements 14 and 15. A bonding layer 21, 22 seals and bonds the sandwich together. Thermally conductive wavelength conversion elements 14 and 15 function not only as wavelength conversion elements, but also thermally spread and sink the heat generated in the embedded LEDs 16. For simplicity, in this cross-sectional view the LED 16 interconnects are not shown in this illustration. However, embeddable LEDs 16 and their use in thermally conductive wavelength conversion elements 14 and 15 are embodiments of this invention and will be further discussed in FIGS. 4 and 9. The thermally conductive wavelength conversion elements 14 and 15 are bulk wavelength converters such that excitation rays 17 emitted by LED 16 is converted to another wavelength range in the form of isotropic emission 18. In this case, isotropic emitter 18 originates within the refractive index of the thermally conductive wavelength converter element 14. The photons emitted at 18 either exit, are waveguided, or are absorbed within thermally conductive thermal emitter 14. In self-cooled emitters with blue excitation LEDs 16, a portion of the blue light emitted by the LED is allowed to escape without wavelength conversion. This is achieved by adjusting the doping level of the wavelength conversion elements. Alternately, bonding layer 22 may also contain or protect powder or thin film wavelength conversion materials 20. In this case excitation rays 22 can be converted to another wavelength range in the form of isotropic emission 23. Isotropic emitter 23 originates in the refractive index of bonding layer 22. The photons emitted in this case also can either exit, waveguide or be absorbed within bonding layer 22 and then potentially pass into or through the other elements comprising the self-cooling emitter. The refractive index (real and complex) determines the amount of light spreading and efficiency of the emitter.

The light emitting element emits light through a light emission surface of the thermally conductive luminescent element. The thermally conductive luminescent element emits heat by thermally spreading and sinking the heat from the light emitting element through a cooling surface of the thermally conductive luminescent element. The light emission surface and the cooling surface are the same surface of said thermally conductive luminescent element.

By controlling the doping level, bulk versus layered, LED mounting configuration, spacing, excitation wavelength, percentage of escape light, emission wavelengths, and absorption and reemission process within the self-cooling emitter, virtually any color light source can be created. By controlling the doping concentration, percentage of waveguiding versus escape light, extraction rates, bulk versus layered, and die spacing, the intensity uniformity of the light source can be controlled. In general, waveguiding of the excitation rays 17 and 22 along with low doping concentration levels are needed to create more uniform light sources. Multiple excitation wavelengths from LEDs 16 to create sources with higher color rendering indexes (CRI) may also be accomplished within the scope of this invention.

FIG. 4 depicts an LED 27 embedded in the wavelength conversion element. The LED 27 contains an active region 26 from which excitation rays 30, 31, 32 and 34 are emitted. Interconnects to the LED are omitted in this figure for clarity. In this case, light is extracted from all sides of the embedded LED. For this to occur efficiently, the bulk of the LED 27 must exhibit low absorption for the emitted light. Low absorption coefficient (alpha) at the emission wavelengths is, therefore, required to minimize absorption losses within the LED itself. As such, an LED with an average alpha of less than 1 cm ⁻¹ at the emission wavelengths is an embodiment of this invention. Even more preferred is an LED with an average alpha less than 1 cm⁻¹ at the emission wavelength of the LED and at the emission wavelengths of the wavelength conversion elements. Low alpha is, therefore, preferred for all materials used in the construction of the LED(s) to be used with said low alpha wavelength conversion elements. Preferred materials for the LED include GaN, AlN, nitride alloys containing gallium, indium, aluminum, and boron, ZnO and its alloys, diamond, undoped SiC, and sapphire. Nitride alloys in particular are preferred because they also exhibit very good resistance to high temperature processing due to an inherently close thermal expansion match with the active region 26. In order to maximize extraction efficiency, the bonding layer 25 that attaches the LED 27 to the wavelength conversion element 24 should also exhibit low alpha and a relatively high refractive index. More preferably, the bonding layer will have a refractive index between that of the LED and the wavelength conversion element (lower than the index of the LED, but higher than the wavelength conversion element). Even more preferred is a bonding or joining layer that is a multiple layer with a graded index of refraction which forms an anti-reflective layer minimizing Fresnel losses between the LED and the wavelength conversion element. Examples of bonding layer materials include, glass frits, antimony oxide, and other high index of refraction transparent materials. While siloxanes and other organic lower curing temperature materials may be used for bonding layer 25, inorganic melt or fusible materials are preferred. High index transparent oxides with melt temperatures under 800° C. are most preferred. In FIG. 4, excitation ray 31 waveguides within thermally conductive transparent element 24 which may include a low doping level luminescent material or a non-luminescent transparent material examples include, cubic zirconia, yag, Al2O3, AlON, Sialon, Silicon oxynitrides, Spinel, ZnS, ZnO, ZnSe, and transparent ceramics. The formation of composites of luminescent powders within thermally conductive transparent or luminescent matrices is a preferred embodiment of the thermally conductive transparent element 24. Excitation ray 30 is depicted to illustrate how certain rays emitted within the critical angle to the normal of the output face of the wavelength conversion element 24 can escape from the thermally conductive transparent element 24 and without undergoing wavelength conversion. The shape of the body of the LED 27 has a large impact on how the rays are extracted from the LED and their interaction with the thermally conductive transparent elements. Another embodiment is depicted by excitation ray 32, which is shown to enter thermally conductive transparent element 28 on which is coated a luminescent layer 29. In this case, wavelength conversion is localized at a distance from the LED determined by the thickness of the thermally conductive transparent element 28. Depending on how the LED is embedded in thermally conductive transparent element 28 and the refractive index of luminescent layer 29 relative to the refractive index of thermally conductive transparent element 28, excitation ray 32 will either enter luminescent layer 33 and be converted into isotropic emission 33 or be reflected within thermally conductive transparent element 28. Thermally conductive transparent element 28 and 24 may also be luminescent, in which case excitation ray 34 may generate isotropic emission 35. By carefully controlling these various properties, the color temperature, efficiency, uniformity and output levels can be controlled. Once optimized, these properties may be maintained and the light sources manufactured at high volume and low cost due to the simplicity of the structure.

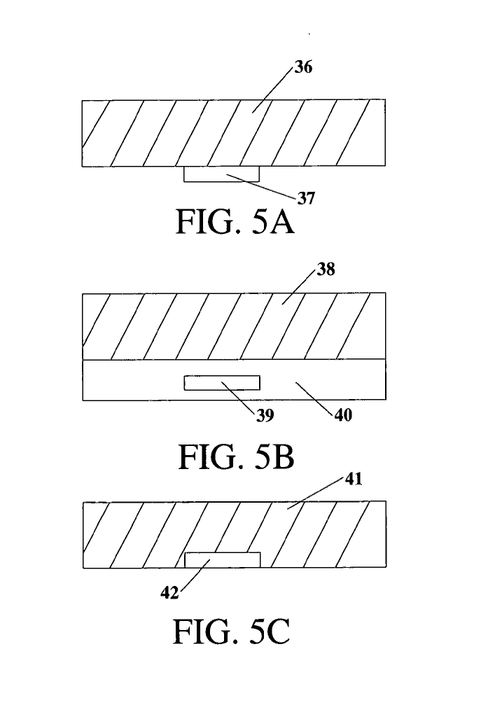

FIG. 5 depicts three different LED mounting configurations. FIG. 5A depicts an LED die 37 directly bonded to the face of the thermally conductive wavelength conversion material 36. The advantage of this configuration is that it eliminates the optical interface between the two materials and forms an intimate thermal bond. The disadvantage is that it requires optically flat surfaces on both the LED output faces and the mating face of the wavelength conversion materials. An alternate mounting method uses melt bondable materials such as high thermal conductivity glasses and glass/ceramic composites. FIG. 5B depicts the use of an intermediary bonding layer 40 such as a glass fit or high index melt bondable material like antimony trioxide to attach LED die 39 to thermally conductive wavelength conversion material 38. This approach removes the constraint on flatness for the LED and melt bondable thermally conductive wavelength conversion material, but can introduce additional optical and thermal interfaces. FIG. 5C depicts a more preferred configuration where LED die 42 is embedded within thermally conductive wavelength conversion material 41. In this case mechanical, laser, or chemical etching means are used to form pockets into thermally conductive wavelength conversion material 41. The pockets can be shaped to match the body of the LED thereby forming a close fit to the thermally conductive wavelength conversion material. This can provide a lower thermal resistance from the LED to the wavelength conversion material and results in better cooling of the LED. The pockets can also aid in locating the LEDs in the manufacturing process. Alternately, trenches may be formed in the wavelength conversion material, which can locate the LED die 42 in one axis. The use of protective/passivation coatings on the LED die to further protect the mesa edge and current spreading layers during high temperature processing is disclosed. In particular the use of polysiloxane, polysilazanes, and other transparent high temperature coatings that cover all the surface of the LED emitting area but the metal contacts is disclosed. Coating thicknesses between 1 and 50 microns are preferred.

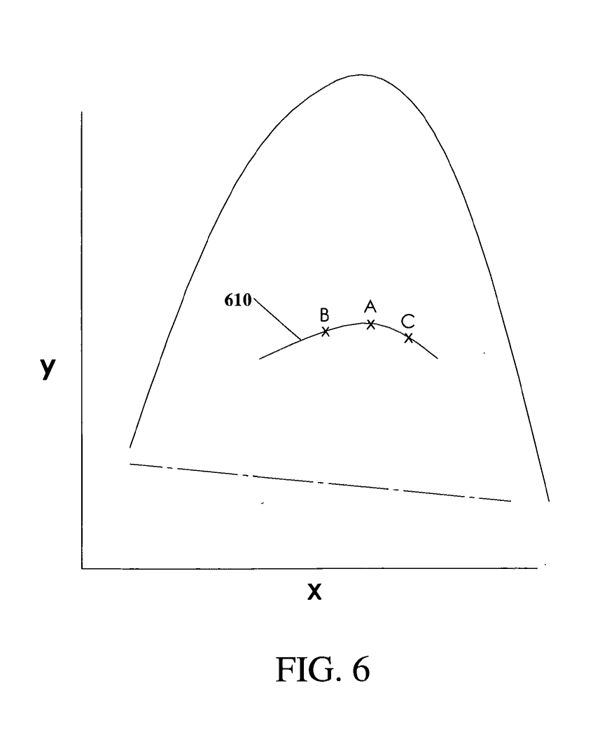

FIG. 6 illustrates a CIE color space chromaticity diagram. Typically, it is desirable to generate lighting that lies along the blackbody curve 610. Points A, B and C depict the relative color temperature with the die mounting configurations 5A, 5B, and 5C, respectively if the wavelength conversion material was the same in all three cases. Point B is a higher color temperature (shifted to blue) because a higher percentage of the blue primary excitation light from the LED will escape the wavelength conversion material before being converted due to restricted solid angle created by the bonding layer. Point A is an intermediate color temperature because there is a larger solid angle into the wavelength conversion than achieved with the mounting configuration shown in FIG. 5B and, therefore, a higher percentage of the light will be converted to longer wavelengths. Point C is lowest color temperature because a higher percentage of the excitation rays meet the waveguiding criteria for the wavelength conversion material and, therefore, more of the excitation rays are converted to longer wavelengths. The use of die containing selective reflective coatings to further restrict the amount of blue light that escapes before being converted is also disclosed.

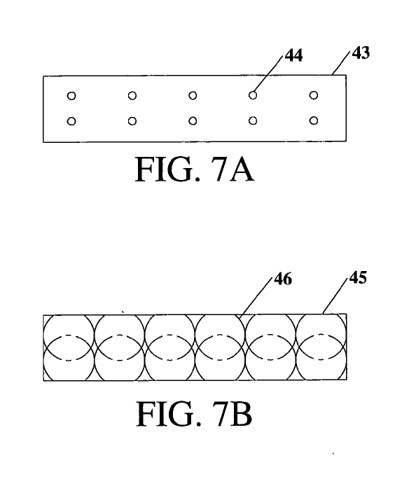

FIG. 7 depicts how mounting configuration, die spacing, thermal conductivity, doping levels, extraction features, and refractive indices can all affect optical uniformity and thermal spreading. FIG. 7A depicts the optical and thermal distribution, the prior art technique, of LED die sandwiched between glass plates as previously depicted in FIG. 1B. Optically, Snell's law determines the escape cone angle in which only a small portion of the internally generated light can escape with a very small area 44 within source area 43. Diffusion elements may be used to redefine an image plane. The heat diffusing from the LED would have a similar pattern (e.g. heat spreading image obtained using a thermal imaging camera). In this case if glass with a low thermal conductivity is used, the low thermal conductivity of the glass sheets restricts the lateral heat spreading and localizes the temperature within the die. FIG. 7B depicts how waveguiding and wavelength conversion (both bulk and layered) can be used to create a more uniform light source by creating a much larger source image area 46 within the wavelength conversion element area 45. Again, a similar image would be seen using a thermal imaging camera. In this case the higher thermal conductivity of the thermally conductive luminescent element enables much better thermal spreading that dissipates the heat generated at the junction of the LED and spreads it over the wavelength conversion element. This result has been verified experimentally resulting in a thermally conductive wavelength conversion element ½ inch×1 inch in area that dissipates 1.8 watts using natural convection while generating over 120 lumens with a uniform output distribution and a color temperature of 310 degrees K. and maintaining a surface temperature under 80 degrees C. and a LED junction temperature under 90 degrees C. with an array of 28 LED chips. The surface brightness was measured at approximately 15,000 ftL. Again the combination of embedded LED chips 28 within a thermally conductive wavelength conversion element with a thermal conductivity greater than 1 W/m/K enables high lumen output and thermally and optical spreads the heat and optical output over an area sufficiently large enough to allow for cooling and a distributed illumination source.

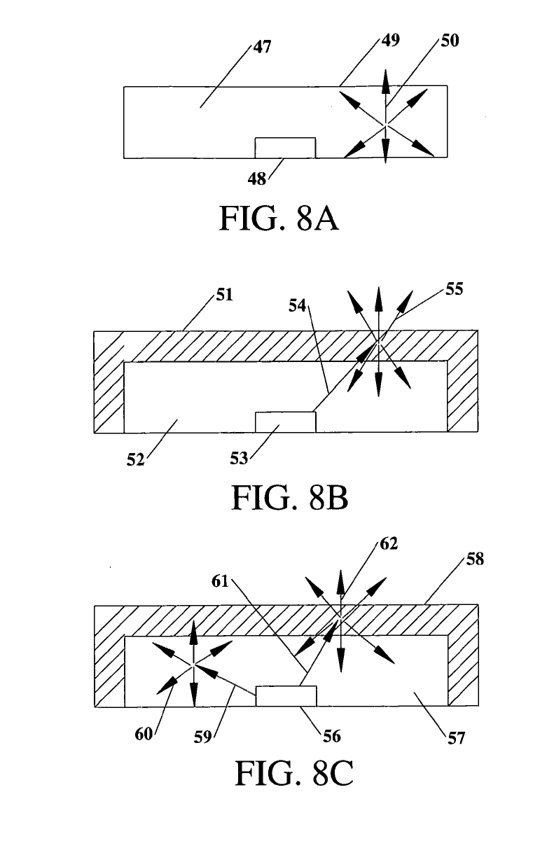

FIG. 8 depicts three different techniques. FIG. 8A depicts LED die 48 embedded within thermally conductive wavelength conversion element 47. In this case excitation ray 49 is converted to isotropic emission 50 within the bulk of thermally conductive wavelength conversion element 47. This element can be a simple crystal transparent on translucent CeYag or other phosphor containing ceramic, as described in U.S. Pat. No. 7,285,791, commonly assigned as the present application and herein incorporated by reference. FIG. 8B depicts LED die 53 embedded within a thermally conductive transparent coated element 52 which may consist of cubic zirconia, or high thermal conductivity glasses, ZnS, ZnSe, ZnO, MgO, ALON, Al2O3, spinel, Sialon, silicon oxynitride, and transparent ceramics and single crystals with thermal conductivity greater than 1 W/m/K. Luminescent coating 51 is coated on the surface of the thermally conductive transparent element 52. In this case, excitation ray 54 is converted to isotropic emission 55 within the luminescent coating 51 on the outer surface of the thermally conductive element 52. In this case, both excitation at a distance and waveguiding can be used to create a more uniform output. FIG. 8C depicts LED die 56 embedded within thermally conductive wavelength conversion element 57 and a luminescent coating 58. In this case, excitation ray 59 is converted to isotropic emission 60 within the bulk of thermally conductive wavelength conversion element 57 and excitation ray 61 is converted to isotropic emission 62 within luminescent coating 58. It should be noted that in all the embodiments of this invention isotropic emission is substantially isotropic, however light directionality may be altered with the appropriate use of refractive index (real and complex), extraction elements (including dichroic filters, photonic structures, and other subwavelength elements) as known in the art and can be incorporated into the self cooling emitter disclosed herein and therefore embodiments of this invention. In the case of FIG. 8C, phosphors may be used to achieve a more efficient and higher CRI light source. It has been found that thin layers of phosphors may be melt bonded onto the thermally conductive elements and the output tuned to alter color temperature or achieve a higher CRI.

FIG. 9A depicts a self cooling emitter with interconnects included. In this example, embedded lateral LED die 64 are bonded into laser cut pockets in thermally conductive wavelength conversion element 63 using a high index glass frit 65 with a melt temperature greater than 400 degrees C. The interconnects are screen printed using a high temperature thick film silver ink that fires at a temperature greater than 200 digress C. As previously discussed, the use of protective coating layers for embedded lateral LED die 64 is an embodiment of this invention. Inter-element bonding layer 66 may be partially applied directly onto embedded lateral LED die 64 prior to mounting into the laser cut pockets at the wafer or die level of manufacturing as added protection for the mesa edges and additional electrical isolation for the silver ink interconnects. Inter-element bonding layer 66 may also contain wavelength conversion material 67 in powder, flake, or rod form. Preferable bonding layer 66 is a melt bondable glass fit with a melting temperature over 300 degrees C. and is used to bond second thermally conductive wavelength conversion layer 68 to form a hermetically sealed self-cooling emitter. Alternately, layer 68 may consist of a thermally conductive reflective layer including but not limited to a metal, a ceramic, a glass, or a composite material. In this case, a directional source is formed which can be thermally cooled using other heat dissipating means through layer 68. Using either of these approaches, both LED die 64 and wavelength conversion material 67 are sealed from the outside environment. This permits the use of lower cost and high efficiency sulfides and other moisture sensitive luminescent materials which cannot be used in prior art approaches that utilize organic low temperature encapsulants that do not adequately protect these moisture sensitive phosphors in real world environments. This enables low cost, high efficiency, light sources to be realized in a lightweight environmentally sealed package. This combination of high efficiency phosphors and elimination of/or need for heavy or bulky appended heatsinks results in over 100 lumens/gram self-cooling emitters to be realized. FIG. 9B depicts one or more thermally conductive transparent elements 69 with luminescent coating 74. Vertical LED die 70 are embedded in thermally conductive transparent element 69 and interconnected using printed interconnect 72. In this configuration, the vertical LED die 70 orientation is substantially orthogonal to the printed interconnect 72 such that printed interconnect 72 can be used to connect vertical LED dies 70 in series allowing for high voltage operation. By increasing the drive voltage more efficient drive configurations can be used thereby increasing the overall system efficiency. Series, series/parallel, anti-parallel connections are also disclosed using this configuration based on 2 dimensional patterning of interconnect 72 on at least one thermally conductive transparent element 69. Interconnect 72 most preferably is a metallic interconnect with a reflectivity greater than 70% for decreased absorption losses within the device. Even more preferably the interconnect 72 is a silver bearing high temperature ink printed and fired at a temperature greater than 400° C. on at least one piece of thermally conductive transparent conductive element 69. Even more preferably vertical LED die 70 are bonded into at least one thermally conductive transparent conductive element 69 using a high temperature bonding material 71. High temperature bonding material 71 preferably is optically transparent to the emission of vertical LED 70 and even more preferably provides a refractive index match between vertical LED 70 and thermally conductive transparent element 69 to increase optical coupling between the two elements. Most preferably high temperature bonding material 71 also has a thermal conductivity greater than 1 W/m/K such that the heat generated within vertical LED die 70 is thermally conducted into thermally conductive transparent element 69. The addition of luminescent materials within high temperature bonding material 71 to convert the emission wavelengths from vertical LED die 70 into other wavelengths is also disclosed. A high temperature bonding material 71 can be used to mount vertical LED die 70 into at least one thermally conductive transparent element 69 followed by printing of interconnect 72 and firing. Using this approach, interconnect 72 directly fires onto vertical LED die 70 making electrical contact to opposites sides of the die. As such high temperature bonding material 71 must be thermally stable up to the firing temperature of interconnect 72. Alternately, interconnect 72 may be fired prior to mounting vertical LED die 70 using high temperature bonding material 71. In either case, high temperature bonding material 71 is substantially transparent to the emission from vertical LED die 70. More specifically, the use of vitreous glass frits, devitrifying glasses, siloxanes, antimony trioxide, and other inorganic materials with a thermal conductivity greater than 0.1 W/m/K are disclosed for high temperature bonding material 71. Melt bondable, solvent and aqueous based materials are also disclosed for use in high temperature bonding material 71. At least one of thermally conductive transparent element 69 has at least one luminescent coating 74 consisting of a transparent overcoat 73 which also has at least one luminescent element 75 within transparent overcoat 73. Transparent overcoat 73 may consist of all the embodiments previously disclosed for high temperature bonding material 71. Luminescent particles, fibers, plates, and combinations may be used to enhance the output, directionality, or scatter characteristics of the at least one luminescent element 75. As an example, 20% by weight Ce:YAG powders having a mean particle size less than 5 microns (at least one luminescent element 75 may be incorporated into a 600° C. melting point glass frit (transparent overcoat 73) and bonded onto cubic zirconia (thermally conductive transparent element 69). In this example, 2% cerium Ce:YAG powder has virtually zero average thermal conductivity due to air gaps between particles and no mechanical integrity by itself. Firing a thin layer (less than 200 microns) of the glass frit/Ce:YAG powder composite (average bulk thermal conductivity greater than 1 W/m/K) onto the sapphire single crystal with greater than 300 microns thick creates a thermally conductive optical system with an average thermal conductivity greater than 10 W/m/K which can not only cool vertical LED die 70 by conducting the heat from the vertical LED die 70 to the outer surface of thermally conductive transparent element 69 and at least one luminescent coating 74 and then the surrounding ambient, but also optically spreads the emission from vertical LED 70 such that a more uniform optical source is created. It is important to note that the thermal conductivity of the at least one luminescent coating 74 should be greater than 0.1 W/m/K for reasonable coating thicknesses to allow for efficient convective cooling of the device. Low thermal conductivity outer layers will greatly increase the junction temperature of the embedded vertical LED die 70 reducing both die life and efficiency. Alternately, the average bulk thermal conductivity of the device consisting of the both the luminescent coating 74 and thermally conductivity transparent element 69 must be sufficiently high enough to spread the heat generated by vertical LED die 70 and the luminescent material out over a large enough surface area to allow for convective cooling to be effective. Most preferably, luminescent coating 74 is less than 300 microns thick with an average bulk thermal conductivity greater than 0.1 W/m/K on a thermally conductive transparent element 69 greater than 300 microns thick having an average bulk thermal conductivity greater than 10 W/m/K resulting in an average bulk thermal conductivity for the device of greater than 1.0 W/m/K. As an example, 100 microns thick coating of 80% glass frit by weight (1 W/m/K) containing 20% CeYag powder (14 W/m/K) with an average bulk thermal conductivity greater than 1 W/m/K on 700 microns thick transparent alumina (30 W/m/K) forms an device with an average thermal conductivity greater than 20 W/m/K. In this example, 28 vertical LED die 70 with an electrical input of 1.5 watts, mounted as shown in FIG. 9B can generate over 200 lumens of white light per square inch of source area with surface temperature under 60 degrees C. and maintaining vertical LED die 70 junction temperature under 90 degrees C. using natural convection only. Alternately, at least one luminescent element 75 may substantially form the majority of at least one luminescent coating 74. As an example, Ce:YAG powder is flame sprayed directly onto thermally conductive transparent element 69. In this example, the at least one luminescent coating 74 consists of thin layer of substantially all Ce:Yag (14 W/m/K) formed from melt bonded particles with substantially no transparent overcoat 73 used. Flame spray, plasma spray, liquid phase epitaxy, high velocity oxygen flame, and sputtering are all disclosed as methods of forming a substantially transparent overcoat 73 free layer of at least one luminescent element 75 on thermally conductive transparent element 69. Typically, die processing is limited to under 300 degrees C. due to interconnect or wafer bonding material limitations. Processing temperature is limited in a LED structure to under 800 degrees C. by thermal degradation of MQWs from indium migration. As such, vertical LED die 70 may also be put on both sides of thermally conductive transparent element 69, interconnected using interconnect 72 and then overcoated with luminescent layer 74. Preferred materials for thermally conductive transparent element 69 is cubic zirconia, ZnS, ZnSe, ZnO, MgO, Yag, Spinel, Beryl, Zincite, GGG, Al203, AlON Sialon, silicon oxynitride, silicon nitride, TPA, and transparent high thermal conductivity glasses, glass/ceramic composites, and transparent/translucent ceramics. Even more preferably, the thermally conductive transparent element has a bulk thermal conductivity greater than 1 W/m/K. More specifically, the average bulk thermally conductive of a volume greater than 1 cubic millimeter is greater than 1 W/m/K. Most preferably, thin luminescent coating 74 has an average bulk thermal conductivity greater than 0.1 W/m/K to allow for sufficient thermal conduction to the outer surface of the device.

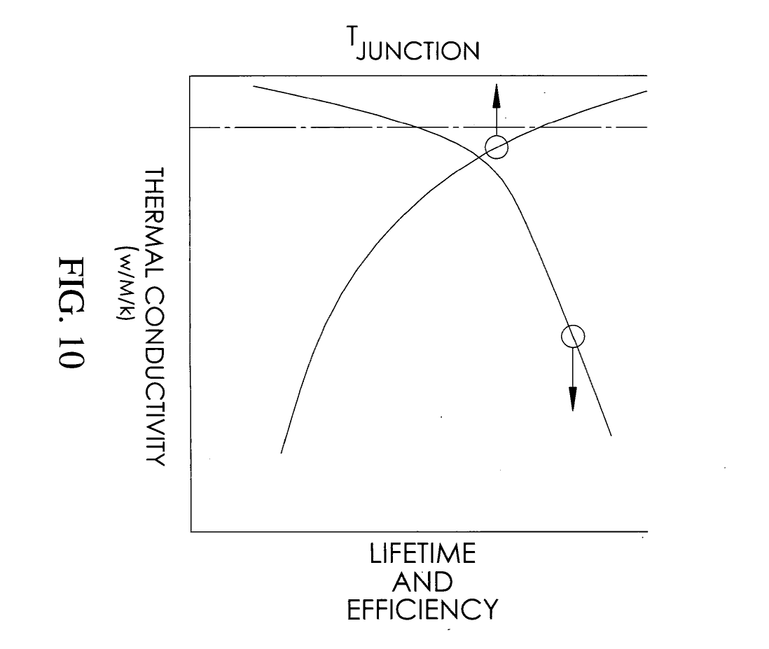

For self-cooled solid-state light sources, as described herein, the thermal conductivity of the luminescent wavelength element is critical. FIG. 10 depicts LED die junction temperature and LED life versus thermal conductivity of the thermally conductive wavelength conversion material. LED die junctions need to be maintained below 140 degrees C. during operation to maintain reasonable life expectations. General lighting applications require 100 to 1000 lumen sources to be useful. For high lumen output devices with reasonable source sizes, the thermal conductivity of the luminescent wavelength conversion elements must be greater than 1 W/m/K or device life will be sacrificed. In addition, high thermal conductivity minimizes droop in lumen output for higher drive currents.

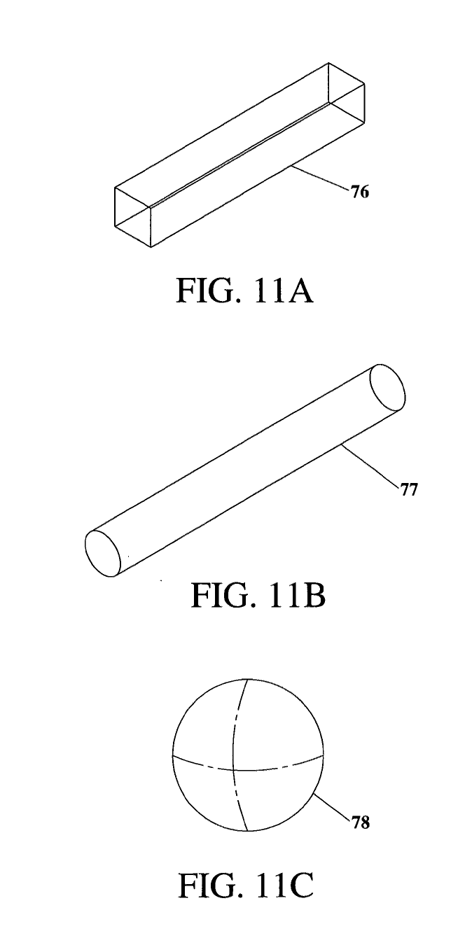

Using the aforementioned techniques and methodologies, omnidirectional or directional multi-face emitting self-cooling light sources may be constructed. The advantage of not having to sink heat to an external heatsink enables radical new designs for solid-state light sources. Self-cooling luminescent light elements can be fabricated with luminance (brightness) of greater than 15,000-foot lamberts. It is preferred to maintain surface luminance under this value for both safety and aesthetic reasons. However, even with this self-imposed limitation high brightness compact light sources may be fabricated using the techniques described herein. For example a 2×2″ two-sided self-cooled emitter at this brightness level will output over 800 lumens (equivalent to an incandescent 60 W light bulb). The self cooled emitters or light slices may be configured in any size to fit different lighting requirements. Light slices may also be configured in shapes other than square or rectangular plates. FIGS. 11A, 11B, and 11C depict various shapes including stick, rod and spherical configurations for the self-cooling emitters. FIG. 11A depicts a long rectangular cross section stick emitter 76. This configuration may be used in applications requiring a long linear light source or one that's compact that has a 360 degree emission pattern. Another major advantage of these self-cooling emitters being fabricated with totally inorganic materials and capable of very high temperature processing is that they can be autoclaved and sterilized for use in medical applications. FIG. 11B depicts a rod emitter 77 and FIG. 11C depicts a spherical emitter 78. Besides these basic shapes (including rectangular thin plate elements described earlier) almost any configuration is possible using the teachings of this invention to dictate the design constraints on the light sources. As long as the thermal conductivity of the luminescent elements is high enough, and the outer area of the luminescent surface exposed to ambient is sufficient, then virtually any shape is possible with this invention. Planar, curved, triangular, or other shapes or combinations of shapes are embodiments of this invention. By combining shapes and orientations virtually any far field distribution pattern is possible. The formation of induced draft structures by combining shapes such that airflow is enhanced may also be advantageously utilized. The addition of blind or through holes, surface structuring or other cooling features in or on the thermally conductive wavelength conversion elements to enhance surface area cooling and our light emission may also be utilized.

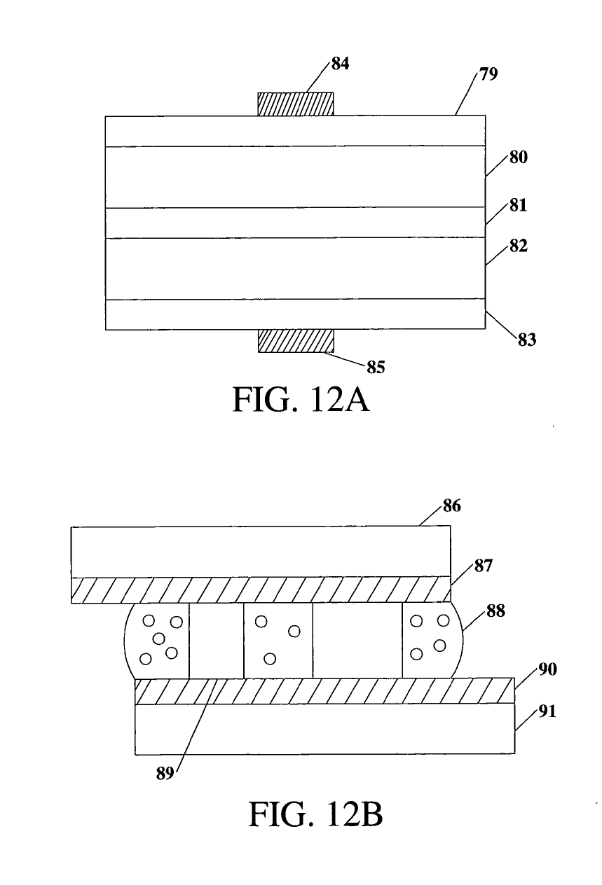

The structure of the LED and its materials of construction can have an influence on the performance of the self-cooling emitters disclosed herein. Preferred LED structures contain no absorbing or opaque materials to fully maximize the light output. Also preferred are freestanding LED substrates without appended growth or transfer substrates attached. These foreign substrates add thermal resistance and light absorption. FIG. 12A depicts a vertical LED structure with an active region 81 with n contact layer 82 and p contact layer 80 with a thickness greater than 10 microns, more preferably with a thickness greater than 20 microns and most preferably with a thickness greater than 30 microns. Transparent conductive layer 70 and 83 are at least 0.3 microns thick grown via dual sided growth. Even more preferably layer 70 and 83 are greater than 2 microns thick with a surface roughness greater than 100 nm RMS. Preferred materials are AZO, IZO, GIZO, as well as other transparent oxides. Zinc oxide alloys grown via chloride, iodine, bromide, and MOCVD are preferred embodiments due to low alpha, optical and thermal interface considerations. Optionally, metal contacts 84 and 85 can be printed or deposited on one or both sides of the device. FIG. 12B depicts a single vertical led 89 with no metal contacts between thermally conductive wavelength conversion layers 86 and 91 with transparent glass bonding layer 88. The robust nature of the LED structure and thickness of the transparent conductive layers in the previous example allow for high temperature hermetic sealing of the LED to form a compact low cost dual sided emitter.

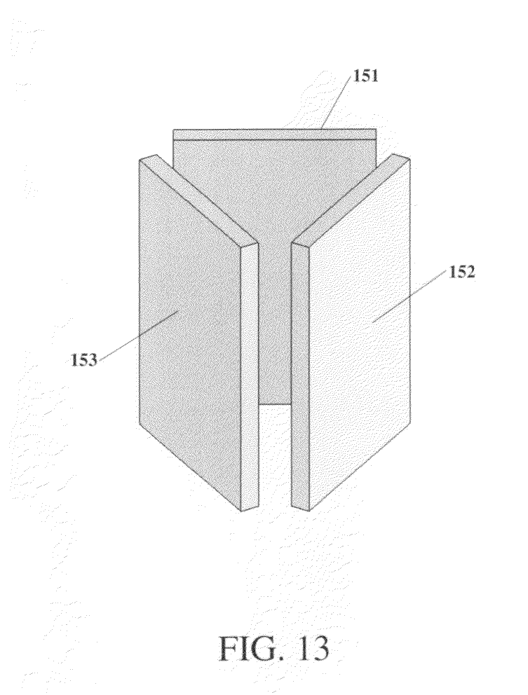

FIG. 13 depicts a three-sided self-cooling light source consisting of three individual emitters 151, 152, and 153. The number, orientation, and spacing of these emitters can be changed to create a wide range of far field patterns. Electrical interconnect is not shown but pins, magnetic connectors, capacitive and inductive contacts can be used. The incorporation of antenna based coupling elements and active energy conversion elements within the emitters 151, 152, and 153 allow radiative energy transfer to be used to power the LEDs within the emitters 151, 152, and 153 without the need for direct electrical connection.

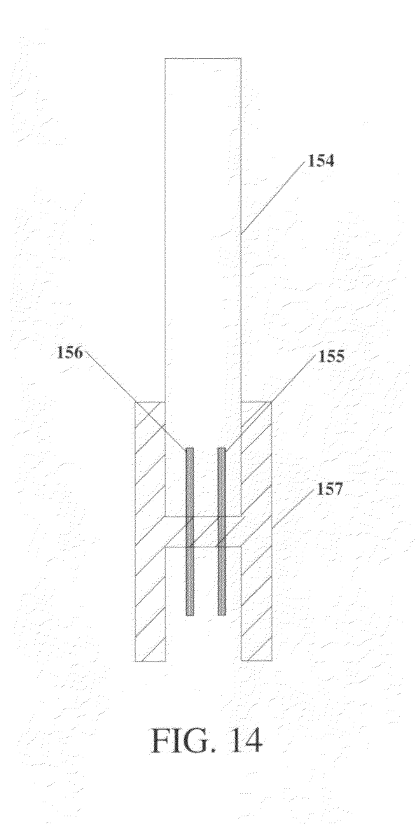

FIG. 14 depicts a self-cooling emitter 154 with a shrouded connector 157 and interconnect pins 155 and 156. A variety of standard connectors are possible including but not limited to USB. The self-cooling emitter 154 may include additional functionality including but not limited to cameras, additional optical elements, thermal sensors, proximity sensors, and power sources or energy storage means.

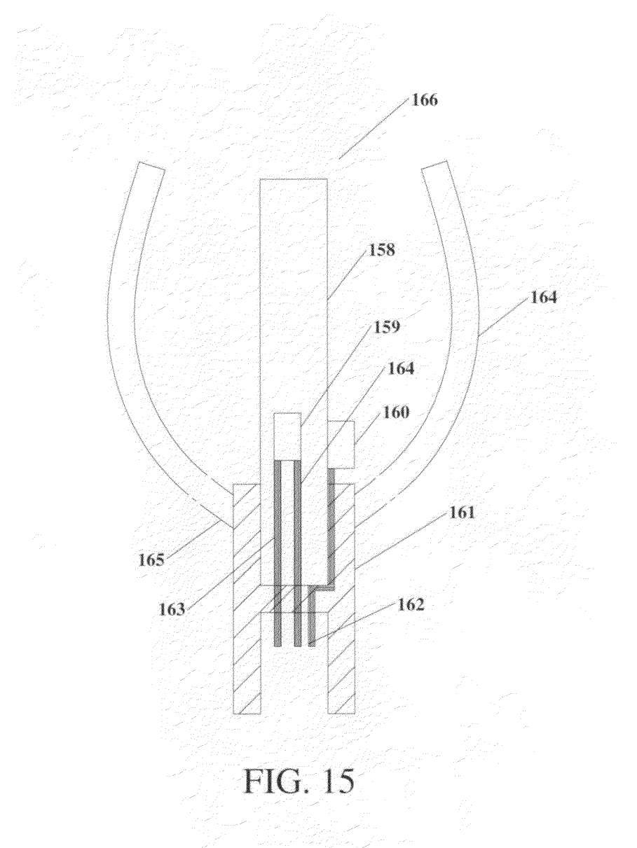

FIG. 15 depicts self-cooling emitter 158 with an embedded temperature sensor 159 and motions sensor 160 mounted onto outside of the self-cooling emitter 158. Connections 162, 163, and 164 are integrated into shrouded housing 161. Using this approach a variety of added functionality can be integrated into the lighting system. The ability to upgrade or modify the lighting system by changing out self-cooling emitters is also disclosed. Additional diffusing or decorative optics 164 maybe mounted to either shrouded connector 161 or self-cooling emitter 158. However, cooling vents 165 and 166 are required to maintain reasonable convection around the self-cooling emitter 158.

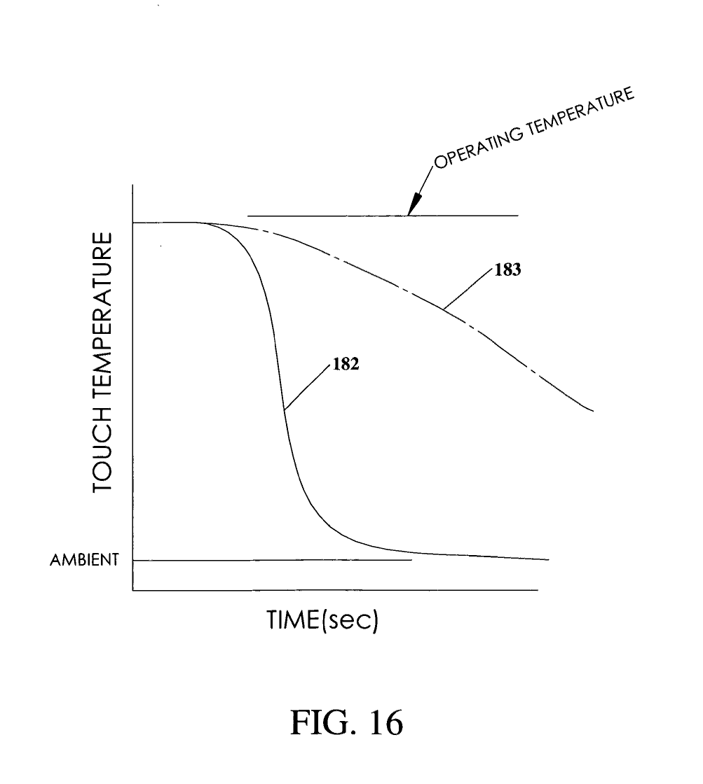

FIG. 16 depicts the cooling response of a light source as it relates to its own thermal mass The self-cooling emitters disclosed in this invention exhibit very low thermal mass as characterized by their lumens per gram properties. A novel attribute of this property is the creation of high output light sources whose touch temperatures rapidly return to ambient once they are turned off. As shown in the graph existing solid-state light source thermal response 183 is very long due to the thermal mass of the heatsink. As such a user may have to wait several minutes for an existing solid-state light source to be safe to handle or remove from the socket. In contrast low thermal mass response 182 rapidly cools to ambient. As such, self-cooling emitters with greater than 30 lumens/gram output are embodiments of this invention. Even more preferably self-cooling emitters with greater than 30 lumens/gram output and thermal time constants less than 30 seconds are embodiments of this invention.

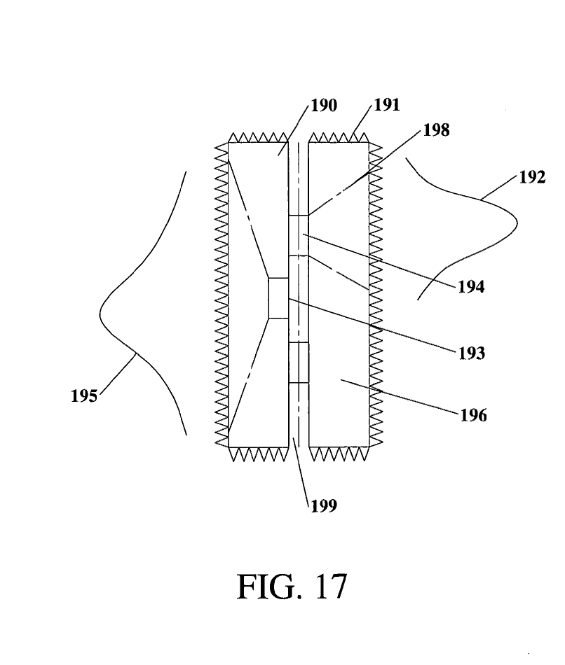

FIG. 17 depicts a self-cooled emitter with optical surface elements to enhance and control the emission of the light from the thermally conductive luminescent elements. These may be formed using laser, lithography, micro-imprint lithography, surface roughening, etc. By controlling the shape of the elements, diffuse or directional lighting may be achieved. These elements can also be used to enhance the efficiency of the light sources by defeating the internal total reflection of light impinging on the outside interface at less than the critical angle. Thermally conductive transparent elements 190 and 196 may or may not be luminescent converters but do exhibit low absorption within the emission wavelengths of emitters 193 and 194 and the emission wavelengths of any of the luminescent elements within bonding layer 199, thermally conductive transparent elements 190 and 196, and/or extraction elements 191. As previously disclosed, the use of luminescent coatings for extraction elements 191 is an embodiment of this invention. As illustrated in the figure, there is a significant difference between an embedded emitter 193 and a non-embedded emitter 194. Snell's law dictates that light emitted from a non-embedded emitter 194 will have a smaller solid angle within thermally conductive transparent layer 196 if the refractive index of the thermally conductive transparent element 196 is less than the refractive index of the non-embedded emitter 194. Since LEDs in general have very high refractive indices there is a solid angle restriction that occurs as the light emitted by non-embedded emitter 194 enters the thermally conductive transparent element 196. It is understood that emission form non-embedded emitter 194 can also go into thermally conductive transparent element 190 but for illustration purposes this is not shown. The difference in solid angle 197 for embedded emitter 193 and solid angle 198 for non-embedded emitter 194 leads to intensity distribution profiles 195 and 192 respectively. As previously disclosed, whether an emitter is embedded or not embedded can be used to adjust the spectral distribution of the source. This figure discloses how the intensity profile across the surface of a solid state light source may also be adjusted using embedded and non-embedded emitters within a solid state light source containing at least one thermally conductive transparent element with extraction elements and may optionally include wavelength conversion means either within the thermally conductive transparent element or within the extraction elements or both.

The following figures show various arrangements of the light slices or self-cooled emitters that in most cases provide omnidirectional illumination while enabling for natural convection cooling.

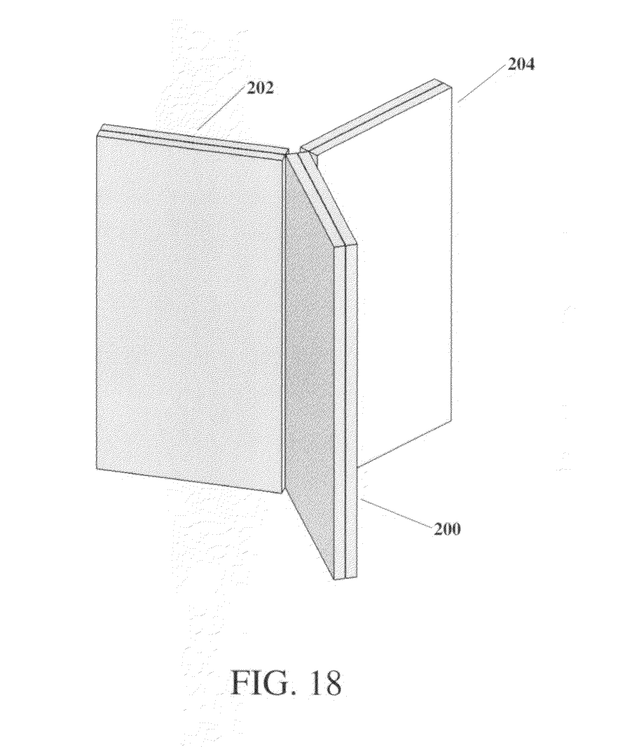

FIG. 18 shows three light slices 200, 202, and 204 meeting on a common vertical axis with their outer edges 120° apart. This provides very uniform output in a 360° horizon. Utilizing ½inch×1 inch light slices this source may provide over 400 lm in total illumination.

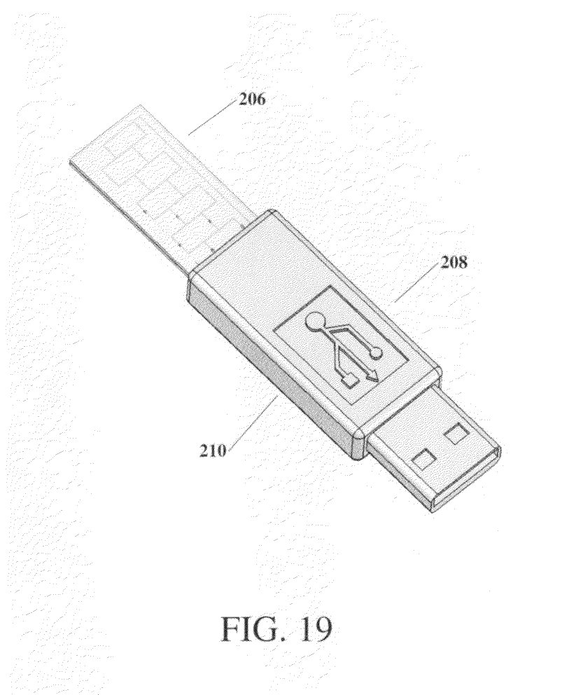

FIG. 19 shows a self-cooled light slice 206 powered via USB with a USB connector 208 attached. The source can be powered by a USB port on a computer or with a USB output power supply. Additional functionality may be included within self cooled light slice 206 and/or USB body 210 including but not limited to directional optical elements (e.g. reflectors), non-directional optical elements (e.g. diffusers), spectrum modifying optical elements (e.g color filters), additional cooling means (e.g. heatpipes, fins, and other heatsinking means), thermal sensing, memory, motion sensing, camera (picture or video, GPS, energy harvesting, battery or other energy storage means, and/or transmitting/communication means to allow for uses including but not limited to mobile lighting, survival, security, smart lighting, energy harvesting, and standardized lighting fixtures. A preferred embodiment is a mobile light source with interchangeable reflectors that clip or otherwise mechanically, magnetically, or adhesively attach to the self-cooled light slice 206 and/or USB body 210.

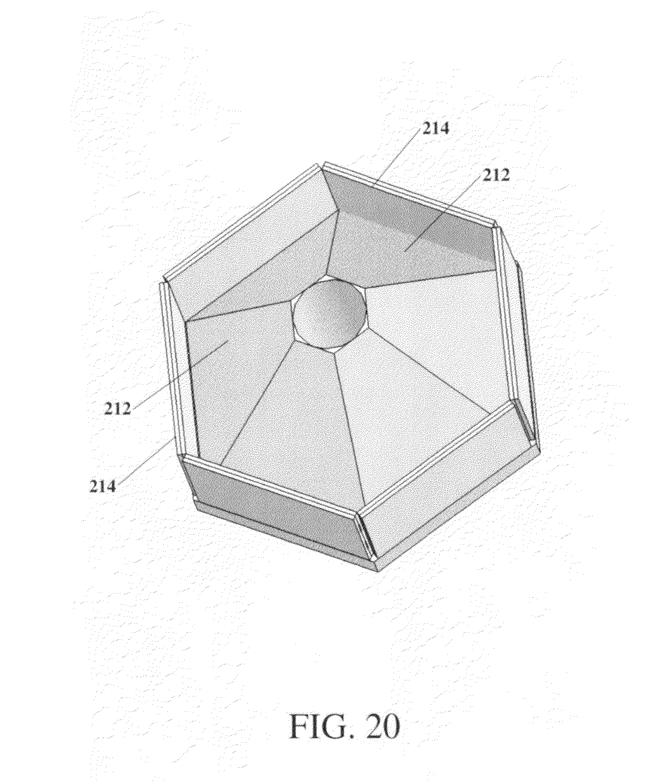

FIG. 20 shows a hexagonal arrangement with six light sticks 212. This arrangement also has faceted mirrors 214 arranged in the center reflecting the light directed inward into upward direction.

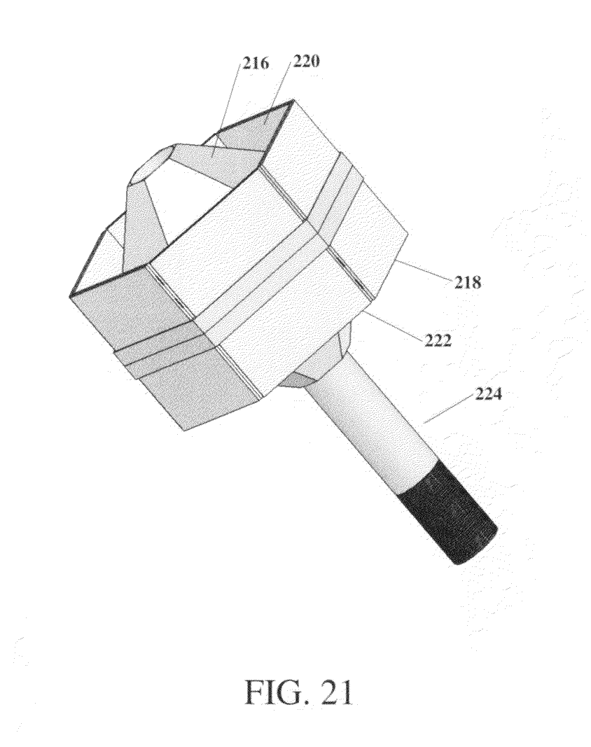

FIG. 21 shows two of these hexagonal arranged light slices 216 and 218 and hexagonal mirrors 220 and 222 with one facing upward and one facing downward forming a high output light source emitting into a 360° solid angle. This source comprising 12 two-sided light slices will provide over 1500 lm in total output without requiring any appended heatsink. In addition the faceted mirror can be made from thin aluminum thereby forming a very light in weight light source with high output that can be utilized in decorative luminaires. A center support 224 functions and mechanical support for the other elements and provides power input to hexagonal arranged light slices 216 and 218.

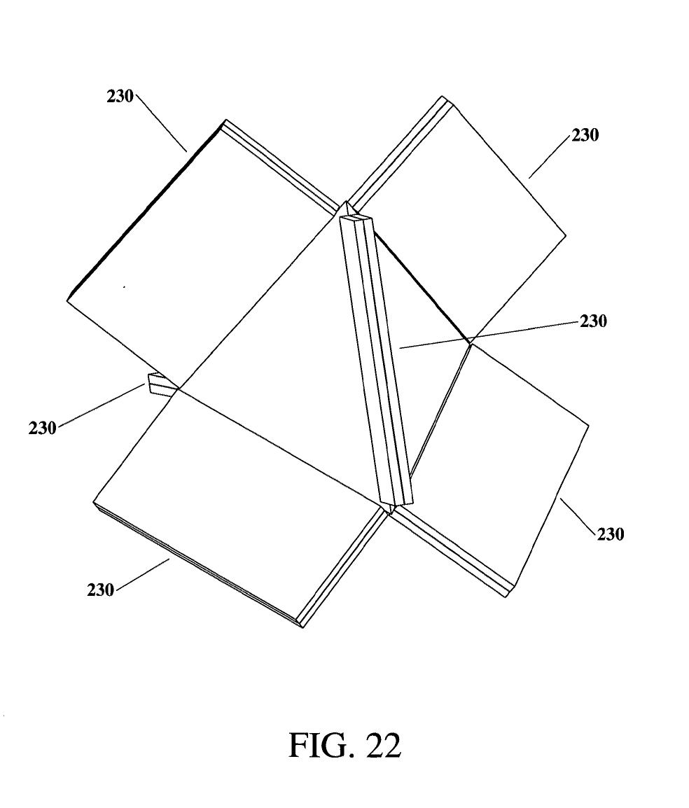

FIG. 22 depicts self-cooled emitting light slices 230 arranged in a fanned configuration. This provides omnidirectional light output with very effective natural cooling to the light slices.

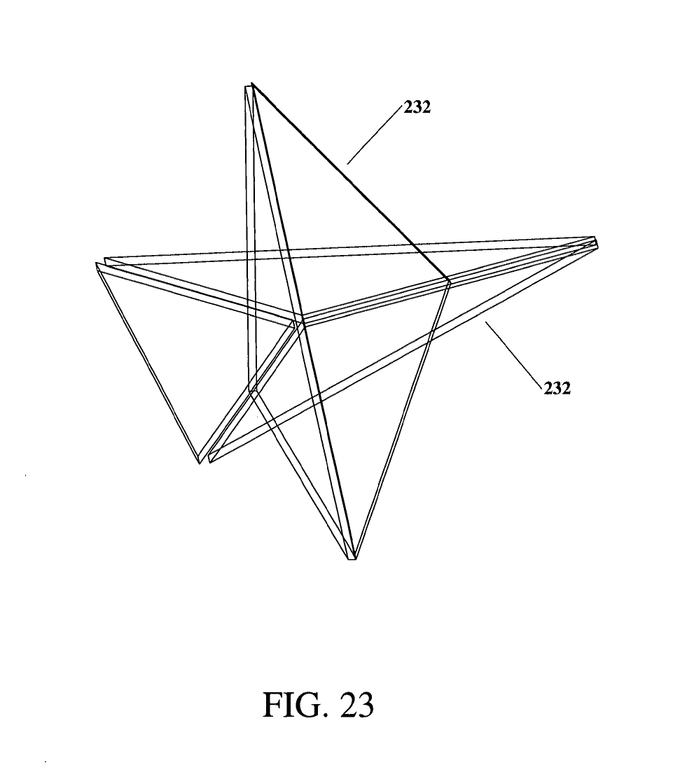

FIG. 23 depicts triangular shaped light slices 232 arranged to form a very decorative but highly functional light source with omnidirectional output.

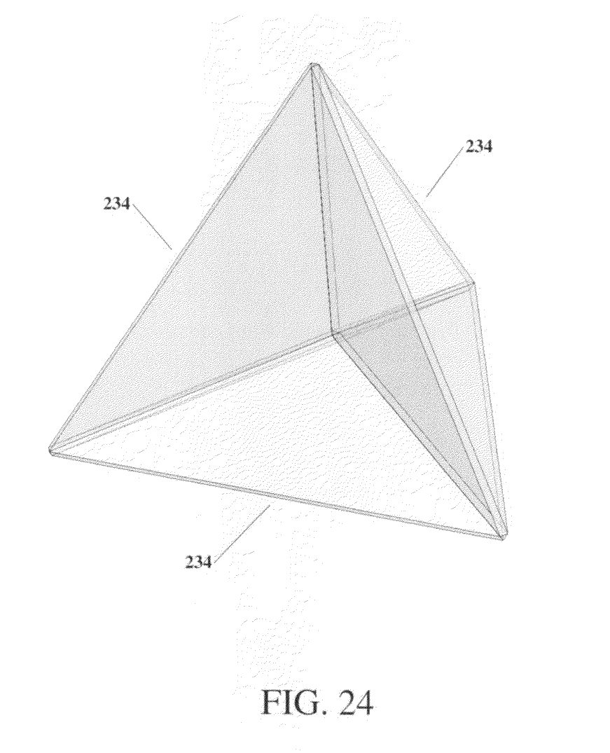

FIG. 24 shows another arrangement utilizing triangular shaped light slices 234 to form a very compact omnidirectional light source without requiring any external heatsink.

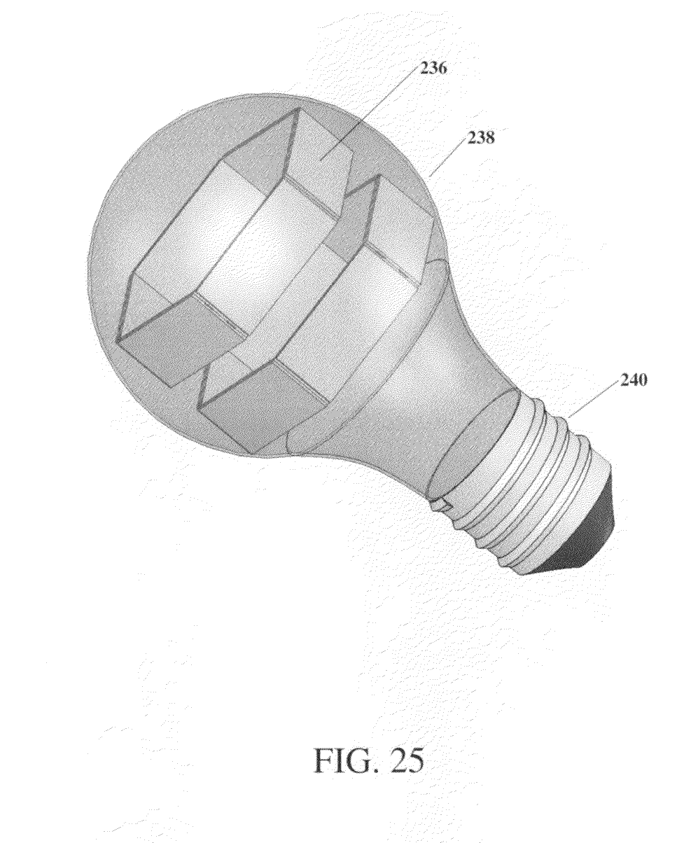

FIG. 25 shows the hexagonal arranged light slices 236 as described above contained in a conventional Edison type light bulb. The envelope 238 for the bulb can be made from either glass or plastic and have holes for cooling either in the top and bottom or throughout. In addition, cooling maybe enhanced using liquid cooling within envelope 238. The driver for the light source that converts from AC to DC is contained in the bulb base 240.

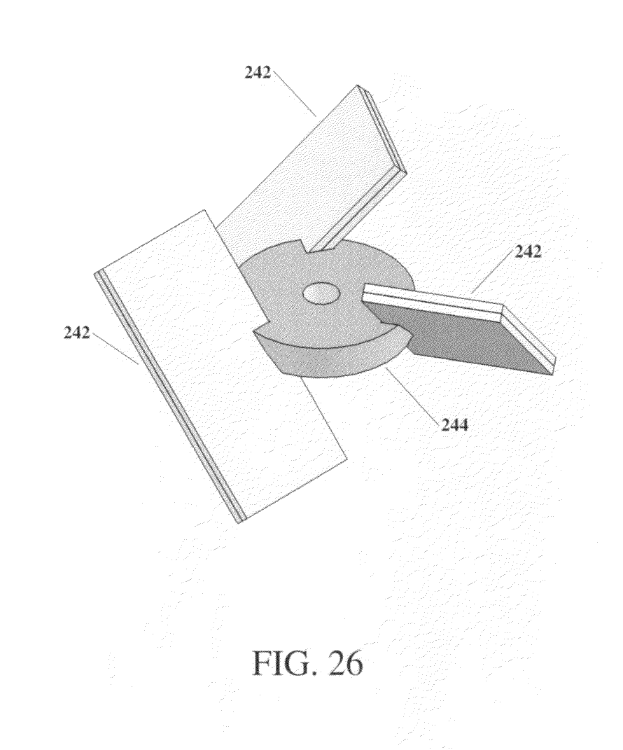

FIG. 26 shows a three-stick light slice 242 arrangement attached to a common hub 244. This common hub can be transparent and/or contain the driver for the three light slices.

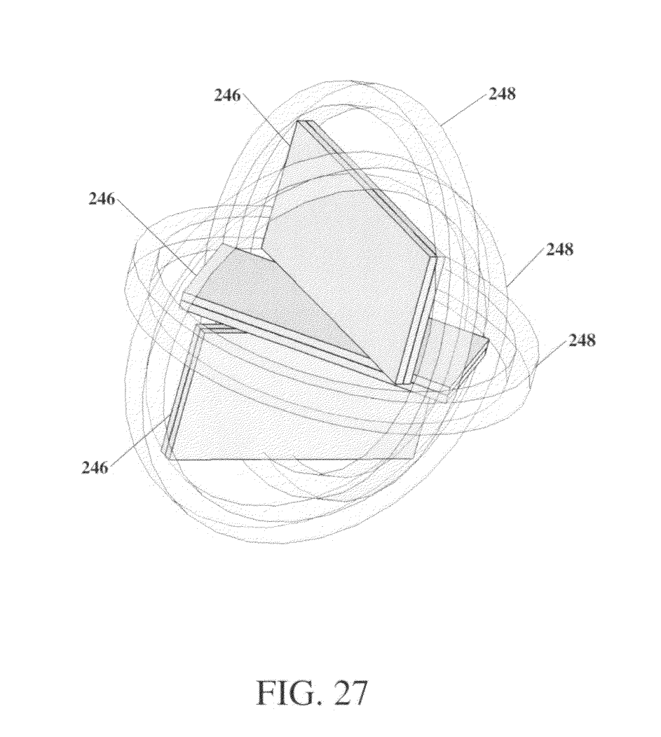

FIG. 27 shows the light 246 arranged to provide an omnidirectional output contained in linked rings 248 for mechanical rigidity. The rings 248 may be made from either metal or clear plastic.

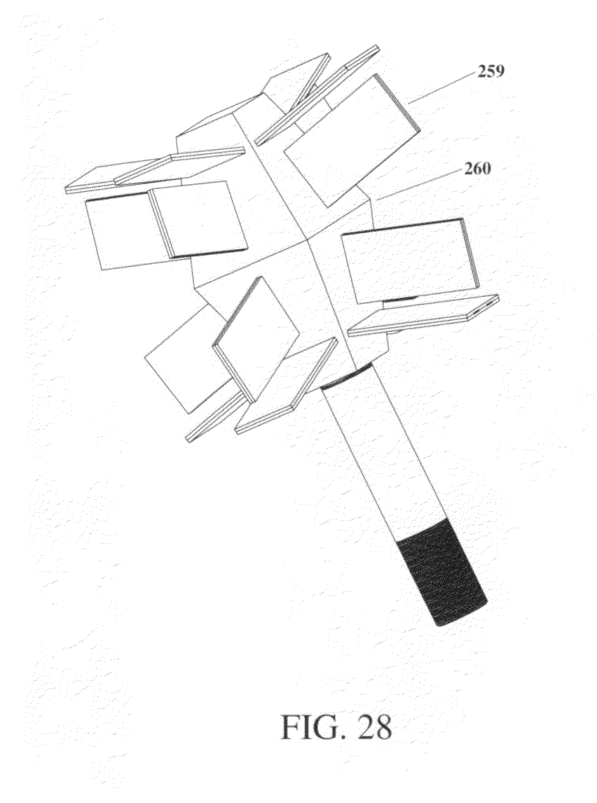

FIG. 28 shows one more arrangement of light sticks 259 to form an omnidirectional output light source. The driver for the sticks may be contained inside the central reflective hub 260 to which they are attached.

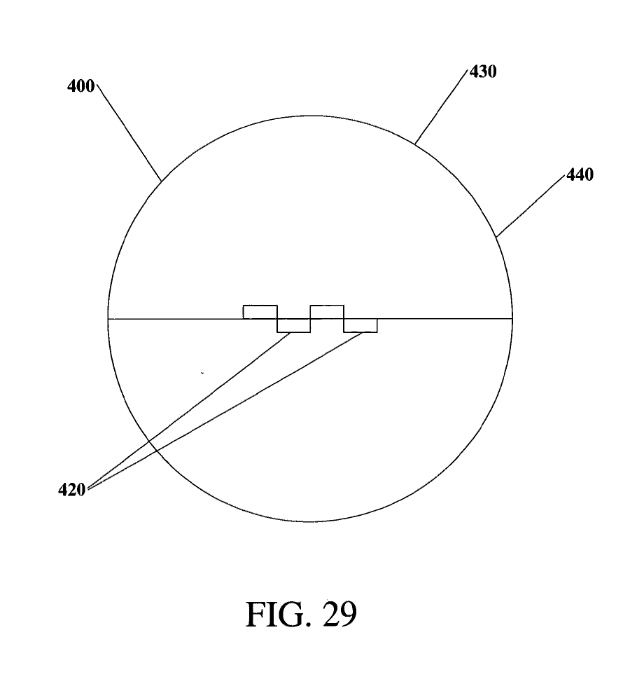

FIG. 29 depicts another preferred embodiment of the invention. The die 420 are located on the central flat surfaces of the two hemispheres 400. The diameter of the sphere when the two halves are joined together is large enough to provide an outer surface area large enough to convectively cool the LEDs 420. LEDs 420 are located close to the center of the thermally conductive wavelength conversion element sphere. This positioning enhances the extraction of light from the thermally conductive wavelength conversion element as light injected 430 by the LEDs 420 will be incident on the outer curved surface 440 of the sphere 400 within the critical angle, avoiding total internal reflection back into the thermally conductive wavelength conversion element. A self-cooling emitter fabricated in this way will have light extraction efficiency and with only a diameter of less than an inch will be able to self-cool with an output of greater than 800 lumens. These spheres or hemispheres can be fabricated with smooth curved outer surfaces or have multiple facets for ease in fabrication while still maintaining high extraction efficiency.

These spheres and the forms of these self-cooling light emitters can be placed in the focal plane of parabolic, ellipsoidal, or other type of reflector to create self-cooling focused light sources. By not requiring an appended heatsink, more efficient and lighter sources can be realized.

It has been shown that these unique self-cooling emitters or light slices can be arranged in innumerable different ways to form lighting systems and/or light sources for almost any type of application. The fact that they weigh very little and don't require bulky appended heatsinks enables their use in decorative luminaires were heretofore LED light sources have been difficult to incorporate because of the serious drawbacks due to the heavy appended heatsinks required to cool them.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

What is claimed is:

1. A self-cooled light emitter comprising
a light emitting element, and
a thermally conductive luminescent element, said light emitting element being embedded in said thermally conductive luminescent element, wherein said thermally conductive luminescent element cools said light emitting element by thermally spreading and sinking heat from said light emitting element and wherein said thermally conductive luminescent element converts light of a first wavelength emitted by said light emitting element into light of a second wavelength, said second wavelength being different from said first wavelength.

2. The self-cooled light emitter of claim 1 wherein said light emitting element is at least one or more light emitting diodes.

3. The self-cooled light emitter of claim 1 wherein said thermally conductive luminescent element exhibits a bulk thermal conductivity greater than 1 W/m/K.

4. The self-cooled light emitter of claim 1 further comprising
a bonding layer between said light emitting element and said thermally conductive luminescent element.

5. The self-cooled light emitter of claim 4 wherein said bonding layer has a refractive index lower than the refractive index of said light emitting element and higher than the refractive index of said thermally conductive luminescent element.

6. The self-cooled light emitter of claim 5 wherein said refractive index of said bonding layer is a graded index of refraction.

7. The self-cooled light emitter of claim 4 wherein said bonding layer contains wavelength conversion material for converting light of a first wavelength emitted by said light emitting element into light of a second wavelength, said second wavelength being different from said first wavelength.

8. The self-cooled light emitter of claim 1 wherein said light emitting element has a first surface and an opposing second surface, and further wherein a first thermally conductive luminescent element is bonded by a first bonding layer to said first surface of said light emitting element and a second thermally conductive luminescent element is bonded by a second bonding layer to said second surface of said light emitting element.

9. The self-cooled light emitter of claim 8 wherein said light emitting element is at least one or more light emitting diodes.

10. The self-cooled light emitter of claim 1 wherein said thermally conductive luminescent element is a composite of luminescent powders within thermally conductive transparent or luminescent matrices.

11. The self-cooled light emitter of claim 2 wherein said at least one or more light emitting diodes are bonded into pockets in said thermally conductive luminescent element by a high index glass fret.

12. The self-cooled light emitter of claim 1 wherein said light emission from said light emitting element is omnidirectional.

13. The self-cooled light emitter of claim 1 wherein said light emission from said light emitting element is directional.

14. The self-cooled light emitter of claim 1 wherein said self-cooled light emitter is configured as a stick, a rod or a sphere.

15. The self-cooled light emitter of claim 1 wherein said self-cooled light emitter has multiple light emitting elements with corresponding multiple thermally conductive luminescent elements.

16. The self-cooled light emitter of claim 1 further comprises
optical surface elements on the light emission surface of said thermally conductive luminescent element to enhance and control the emission of the light from said thermally conductive luminescent elements.

17. The self-cooled light emitter of claim 1 wherein said light emitting element emits light through a light emission surface of said thermally conductive luminescent element and wherein said thermally conductive luminescent element emits heat from said light emitting element through a cooling surface of said thermally conductive luminescent element, and further wherein said light emission surface of said thermally conductive luminescent element and said cooling surface of said thermally conductive luminescent element are the same surface of said thermally conductive luminescent element.

18. The self-cooled light emitter of claim 1 wherein said thermally conductive luminescent element is a transparent ceramic.

19. The self-cooled light emitter of claim 1 wherein said light emitting element emits light and wherein a portion of said emitted light is waveguided within said thermally conductive luminescent element.

20. The self-cooled light emitter of claim 1 wherein said thermally conductive luminescent element forms a hermetically sealed, naturally convectively cooled, solid-state light source for said light emitting element.
